(19) United States
(12) Patent Application Publication
(10) Pub. No.: US 2021/0296603 A1
(43) Pub. Date: Sep. 23, 2021

(54) PHOTOELECTRIC CONVERSION ELEMENT, PHOTOELECTRIC CONVERSION ELEMENT MODULE, ORGANIC THIN-FILM SOLAR CELL, ELECTRONIC APPARATUS, AND POWER SUPPLY MODULE

(71) Applicant: RICOH COMPANY, LTD., Tokyo (JP)

(72) Inventors: Ryota ARAI, Shizuoka (JP); Takahiro IDE, Shizuoka (JP)

(21) Appl. No.: 17/262,062

(22) PCT Filed: Jul. 11, 2019
(86) PCT No.: PCT/JP2019/027567

§ 371 Date: Jan. 21, 2021

(30) Foreign Application Priority Data
Jul. 31, 2018 (JP) 2018-143869
Feb. 1, 2019 (JP) 2019-016996

(51) Int. Cl. H01L 51/42; H01L 51/00; H01L 51/44

(52) U.S. Cl. CPC H01L 51/4253; H01L 51/0068; G06F 3/021; H01L 51/0047; H01L 51/442; H01L 51/0074

(57) ABSTRACT

A photoelectric conversion element is provided which includes a first electrode, an electron transport layer, a photoelectric conversion layer, a hole transport layer, a second electrode, and an insulating layer each overlying a substrate. The first electrode includes a transparent conductive thin-film layer (a), a metal thin-film layer, and a transparent conductive thin-film layer (b). The electron transport layer contains metal oxide particles. The photoelectric conversion layer contains two or more organic materials. The photoelectric conversion element satisfies the following relation: 7.0≤T/D≤40.0 where D represents an average particle diameter of the metal oxide particles and T represents an average thickness of the photoelectric conversion layer.

### TECHNICAL FIELD

The present disclosure relates to a photoelectric conversion element, a photoelectric conversion element module, an organic thin-film solar cell, an electronic apparatus, and a power supply module.

### BACKGROUND ART

In recent years, the driving power for an electronic circuit has become extremely small. It is now possible to drive various types of electronic components, such as sensors, with weak electric power (in the order of μW). Sensors are utilized as standalone power supplies that can generate and consume power on the spot and are expected to be applied to environmental power generating elements. Among these, photoelectric conversion elements are attracting attention as elements that can generate power anywhere with light. In particular, photoelectric conversion elements which have flexibility are expected to be applied to wearable devices capable of following various curved surfaces.

Generally, organic thin-film solar cells are expected as high-efficiency photoelectric conversion elements which have flexibility.

Various proposals have been made for flexible organic thin-film solar cells.

For example, Patent Literature 1 describes an organic thin-film solar cell having a negative electrode, an electron transport layer, a photoelectric conversion layer containing an organic material, a hole transport layer, and a positive electrode in this order on a support. Patent Literature 1 further describes that a sealant may be provided on the positive electrode.

### CITATION LIST

### Patent Literature

PTL 1: Japanese Unexamined Patent Application Publication No. 2014-60351

### SUMMARY OF INVENTION

### Technical Problem

An object of the present invention is to provide a photoelectric conversion element having excellent photoelectric conversion performance and excellent resistance to bending, capable of maintaining high photoelectric conversion performance even when subjected to a bending processing.

### Solution to Problem

According to an embodiment of the present invention, provided is a photoelectric conversion element including a first electrode, an electron transport layer, a photoelectric conversion layer, a hole transport layer, a second electrode, and an insulating layer each overlying a substrate. The first electrode includes a transparent conductive thin-film layer (a), a metal thin-film layer, and a transparent conductive thin-film layer (b). The electron transport layer contains metal oxide particles. The photoelectric conversion layer contains two or more organic materials. The photoelectric conversion element satisfies the following relation:

7.0≤T/D≤40.0

where D represents an average particle diameter of the metal oxide particles and T represents an average thickness of the photoelectric conversion layer.

### Advantageous Effects of Invention

According to an embodiment of the present invention, a photoelectric conversion element having excellent photoelectric conversion performance and excellent resistance to bending, capable of maintaining high photoelectric conversion performance even when subjected to a bending processing, is provided.

### BRIEF DESCRIPTION OF DRAWINGS

The accompanying drawings are intended to depict example embodiments of the present invention and should not be interpreted to limit the scope thereof. The accompanying drawings are not to be considered as drawn to scale unless explicitly noted. Also, identical or similar reference numerals designate identical or similar components throughout the several views.

FIG. 1 is a cross-sectional view of a photoelectric conversion element according to an embodiment of the present invention.

FIG. 2 is a cross-sectional view of the first electrode included in the photoelectric conversion element illustrated in FIG. 1.

FIG. 3 is a block diagram of a mouse for a personal computer as an electronic apparatus according to an embodiment of the present invention.

FIG. 4 is a schematic external view of the mouse illustrated in FIG. 3.

FIG. 5 is a block diagram of a keyboard for a personal computer as an electronic apparatus according to an embodiment of the present invention.

FIG. 6 is a schematic external view of the keyboard illustrated in FIG. 5.

FIG. 7 is another schematic external view of the keyboard illustrated in FIG. 5.

FIG. 8 is a block diagram of a sensor as an electronic apparatus according to an embodiment of the present invention.

FIG. 9 is a block diagram of a turntable as an electronic apparatus according to an embodiment of the present invention.

FIG. 10 is a block diagram of an electronic apparatus according to an embodiment of the present invention.

FIG. 11 is a block diagram of the electronic apparatus illustrated in FIG. 10 further including a power supply IC.

FIG. 12 is a block diagram of the electronic apparatus illustrated in FIG. 11 further including a power storage device.

FIG. 13 is a block diagram of a power supply module according to an embodiment of the present invention.

FIG. 14 is a block diagram of the power supply module illustrated in FIG. 13 further including a power storage device.

### DESCRIPTION OF EMBODIMENTS

The terminology used herein is for the purpose of describing particular embodiments only and is not intended to be limiting of the present invention. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Within the context of the present disclosure, if a first layer is stated to be “overlaid” on, or “overlying” a second layer, the first layer may be in direct contact with a portion or all of the second layer, or there may be one or more intervening layers between the first and second layer, with the second layer being closer to the substrate than the first layer.

Photoelectric conversion elements such as organic thin-film solar cells are utilized by being stuck to curved surfaces or complex shapes other than flat surfaces, such as the body of an automobile or the roof of a building. Therefore, they are required to exhibit excellent photoelectric conversion efficiency even after being bent.

The inventors of the present invention prepared a flexible organic thin-film solar cell and examined it variously through a bend test.

The organic thin-film solar cell was prepared using generally well-known members. Specifically, on a substrate, a transparent electrode comprising indium-doped tin oxide (ITO), an electron transport layer containing a metal oxide such as zinc oxide and titanium oxide, a photoelectric conversion layer containing at least two or more organic materials, a hole transport layer, and a metal electrode were formed. The substrate on which these structural members were stacked was adhered with a sealant. As a result of the bend test for this organic thin-film solar cells, a large decrease of photoelectric conversion efficiency was confirmed.

The inventors examined this result and found that defects had occurred due to bending at three points, i.e., the ITO electrode, the electron transport layer, and the metal electrode, and these defects had caused the decrease of photoelectric conversion efficiency. When the organic thin-film solar cell is bent, a stress is applied to each layer to cause cracks in the ITO electrode and the electron transport layer and peeling at the bonding interface between the sealant and the metal electrode.

The organic thin-film solar cell described in Patent Literature 1 does not sufficiently solve the problem of crack and peeling, and has room for improvement in resistance to bending.

The inventors of the present invention have found that the photoelectric conversion element or organic thin-film solar cell with the following configuration has excellent photoelectric conversion performance and excellent resistance to bending and is capable of maintaining high photoelectric conversion performance even when subjected to a bending processing.

Photoelectric Conversion Element

The photoelectric conversion element includes, on a substrate, a first electrode, an electron transport layer containing at least metal oxide particles, a photoelectric conversion layer containing at least two or more organic materials, a hole transport layer, a second electrode, and an insulating layer.

Hereinafter, an organic thin-film solar cell, as an example of the photoelectric conversion element, is described with reference to the drawings. It is to be noted that the present invention is not limited to the embodiments described below and include other embodiments. Any addition, modification, or deletion can be made to these embodiments within the scope in which one skilled in the art can conceive. Any of these embodiments is included within the scope of the present invention as long as the features and effects of the present invention are demonstrated.

In the present disclosure, a photoelectric conversion element refers to an element that converts light energy into electrical energy or an element that converts electrical energy into light energy. Specific examples of the photoelectric conversion element include, but are not limited to, solar cells and photodiodes.

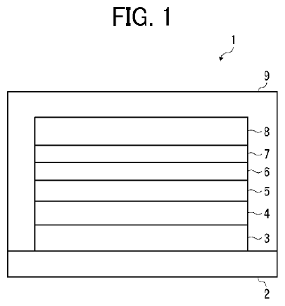

FIG. 1 is a cross-sectional view of an organic thin-film solar cell. Referring to FIG. 1, an organic thin-film solar cell 1 includes a substrate 2, a first electrode 3, an electron transport layer 4, a photoelectric conversion layer 5, a hole transport layer 6, a second electrode 7, an insulating layer 8, and a sealant 9.

The first electrode 3, the electron transport layer 4, the photoelectric conversion layer 5, the hole transport layer 6, the second electrode 7, and the insulating layer 8 are stacked, in this order, overlying the substrate 2. In addition, as illustrated in FIG. 1, the sealant 9 adheres to the insulating layer 8 and the substrate 2 from the top of the insulating layer 8 so as to cover the stacked body formed on the substrate 2.

Substrate

The substrate is composed of a film having transparency and flexibility.

Examples of the film include, but are not limited to, polyester films such as polyethylene terephthalate films, polycarbonate films, polyimide films, polymethyl methacrylate films, polysulfone films, and polyetheretherketone films. Examples of the film further includes thin-film glass having a thickness of 200 μm or less.

Among these films, polyester films, polyimide films, and thin-film glass are preferable for easy production and cost.

The substrate which is composed of a resin preferably has a gas barrier layer.

The gas barrier layer refers to a layer having a function of preventing permeation of water vapor and oxygen, and any known layer having such a function can be used without particular limitation. For example, an aluminum-coated resin substrate and a gas barrier layer described in Japanese Patent No. 5339655 or Japanese Unexamined Patent Application Publication No. 2014-60351 may be used.

First Electrode

The first electrode comprises a transparent conductive thin-film layer (a), a metal thin-film layer, and a transparent conductive thin-film layer (b).

More specifically, in the first electrode, the transparent conductive thin-film layer (a), the metal thin-film layer, and the transparent conductive thin-film layer (b) are stacked in this order.

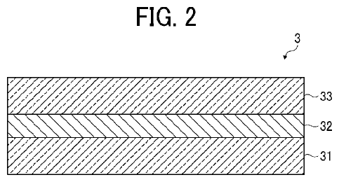

FIG. 2 is a cross-sectional view of the first electrode. Referring to FIG. 2, the first electrode 3 includes the transparent conductive thin-film layer (a) 31, the metal thin-film layer 32, and the transparent conductive thin-film layer (b) 33. As illustrated in FIG. 2, in the first electrode 3, the transparent conductive thin-film layer (a) 31, the metal thin-film layer 32, and the transparent conductive thin-film layer (b) 33 are stacked in this order.

The transparent conductive thin-film layer (a) and the transparent conductive thin-film layer (b), sandwiching the metal thin-film layer, may be made of either the same material or different materials. Preferred materials used for the transparent conductive thin-film layers are those excellent in transparency and conductivity as much as possible.

Materials suitably used for the transparent conductive thin-film layers include, but are not limited to, tin-doped indium oxide (ITO), zinc-doped indium oxide (IZO), zinc oxide (ZnO), aluminum-doped zinc oxide (AZO), gallium-doped zinc oxide (GZO), and tin oxide (SnO₂). Among these, oxides such as ITO, IZO, and AZO are preferable. The thickness of the transparent conductive thin-film layer is usually 30 nm or more, preferably from 40 to 150 nm.

The surface resistivity of the first electrode is preferably 50Ω/□ or less, more preferably 30Ω/□ or less, most preferably 20Ω/□ or less.

The permeability of the first electrode is preferably high in terms of conversion efficiency, and is usually 60% or higher, preferably 70% or higher. The upper limit is not particularly limited, but is usually 90% or less.

Preferred materials for the metal thin-film layer are materials having as high electrical conductivity as possible, such as silver and silver alloy.

The film thickness of the metal thin-film layer is less than 15 nm, preferably 10 nm or less, more preferably 8 nm or less. In addition, the film thickness is preferably 5 nm or more, more preferably 6 nm or more, most preferably 7 nm or more.

The respective film thicknesses of the transparent conductive thin-film layer (a), the metal thin-film layer, and the transparent conductive thin-film layer (b) is determined in consideration of optical properties and electrical properties. The total film thickness of the first electrode is the sum of these film thicknesses.

The first electrode in a three-layer structure comprising the transparent conductive thin-film layer (a), the metal thin-film layer, and the transparent conductive thin-film layer (b) is less likely to cause cracking upon bending and has higher mechanical durability compared to conventional transparent conductive films in a one-layer structure.

Electron Transport Layer

The electron transport layer is formed on the first electrode.

The electron transport layer contains at least metal oxide particles. The electron transport layer may be a film formed with a coating liquid in which nanoparticulate metal oxide is dispersed.

The metal oxide particles preferably comprise at least one of zinc oxide, titanium oxide, and tin oxide. The metal oxide particles may be doped with other metals.

Specific examples of the metal oxide used for the electron transport layer include, but are not limited to, zinc oxide, aluminum-doped zinc oxide, gallium-doped zinc oxide, titanium oxide, and tin oxide.

The average particle diameter (D) of the nanoparticulate metal oxide particles is preferably from 1 to 50 nm, more preferably from 5 to 20 nm.

The film thickness of the electron transport layer is preferably from 10 to 60 nm, more preferably from 15 to 40 nm.

The average particle diameter (D) of the metal oxide particles can be measured as follows. Procedure for Measuring Average Particle Diameter (D)

A solution of nanoparticles is put into a glass nebulizer using a micropipette. The solution is sprayed by the nebulizer onto a grid with a collodion membrane for TEM (transmission electron microscope). The grid is subjected to carbon deposition by a PVD (physical vapor deposition) method and then observed with a transmission electron microscope to acquire an image of the particles. The acquired image is subjected to image processing to measure the particle diameter of the particles.

In addition, a cross-section of the organic thin-film solar cell is observed with a transmission electron microscope to acquire an image, and the image is subjected to image processing for particle recognition and measure the particle diameter of the metal oxide particles. The procedures for cross-sectioning and the TEM equipment are conventionally known ones.

In the present disclosure, the average particle diameter is determined by measuring the particle diameters of at least 100 randomly-selected metal oxide particles and calculating the average value thereof.

Preferably, the electron transport layer comprises a first electron transport layer containing the metal oxide particles and a second electron transport layer formed between the first electron transport layer and the photoelectric conversion layer.

The second electron transport layer preferably contains an amine compound represented by the following general formula (4).

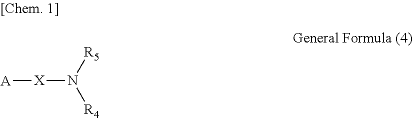

In the general formula (4), each of R₄ and R₅ independently represents a substituted or unsubstituted alkyl group having 1 to 4 carbon atoms. X represents a divalent aromatic group having 6 to 14 carbon atoms or an alkyl group having 1 to 4 carbon atoms. R₄ and R₅ may share bond connectivity to form a ring. A represents any of the following substituents.

—COOH

—P(═O)(OH)₂

—Si(OH)₃ [Chem. 2]

Photoelectric Conversion Layer

The photoelectric conversion layer is formed on the electron transport layer.

The photoelectric conversion layer contains at least two or more organic materials. The photoelectric conversion layer further contains other components as necessary.

Preferably, one of the two or more organic materials (hereinafter “first organic material”) contained in the photoelectric conversion layer is a donor organic material. Preferably, other one of the two or more organic materials (hereinafter “second organic material”) is an acceptor organic material. Preferably, the photoelectric conversion layer may have a bulk heterostructure in which these materials are mixed.

The donor organic material is not particularly limited. Preferred examples thereof include a π electron conjugated compound having a highest occupied molecular orbital (HOMO) level of from 5.1 to 5.5 eV.

More specific examples thereof include, but are not limited to, conjugated polymers obtained by coupling various aromatic derivatives (such as thiophene, fluorene, carbazole, thienothiophene, benzodithiophene dithienosilole, quinoxaline, and benzothiadiazole), and low-molecular conjugated compounds having a clearly determined molecular weight such as porphyrins and phthalocyanines. In addition, a donor-acceptor-linked organic material that has an electron donating site and an electron accepting site in the molecule may also be used.

Among the donor organic materials, an electron donor material (P-type semiconductor) comprising a low-molecular conjugated compound having a number average molecular weight of 10,000 or less is preferable.

More preferably, the number average molecular weight is 5,000 or less.

Specific examples of the first organic material among the two or more organic materials contained in the photoelectric conversion layer include a compound represented by following general formula (1). In particular, the compound represented by following general formula (1) is a preferred example of the electron donor (P-type semiconductor) having a highest occupied molecular orbital (HOMO) level of from 5.1 to 5.5 eV and a number average molecular weight of 10,000 or less, which is one example of the donor organic materials.

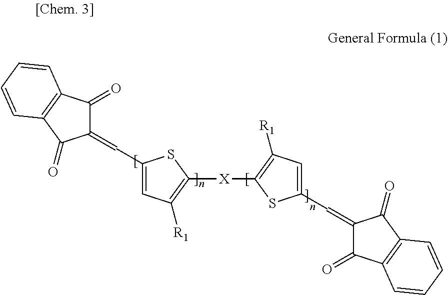

In the general formula (1), R₁ represents an alkyl group having 2 to 8 carbon atoms. n represents an integer of 1 or 2. X represents the following general formula (2) or (3).

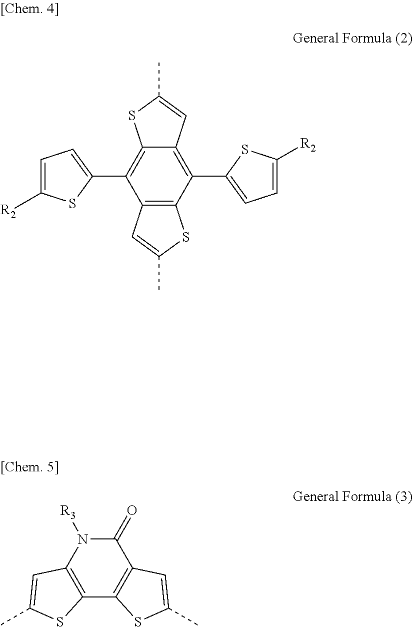

In the general formulae (2) and (3), each of R₂ and R₃ independently represents a straight-chain or branched alkyl group.

The acceptor organic material as the second organic material is not particularly limited. Preferred examples thereof include a π electron conjugated compound having a lowest unoccupied molecular orbital (LUMO) level of from 3.5 to 4.5 eV.

Specific examples of the second organic material include, but are not limited to, electron acceptors (N-type semiconductors) such as fullerene and derivatives thereof, naphthalene tetracarboximide derivatives, and perylene tetracarboximide derivatives. Among these, fullerene derivatives are preferable.

Specific examples of the fullerene derivatives include, but are not limited to, C60, methyl phenyl-C61-butyrate (i.e., a fullerene derivative described as PCBM, [60]PCBM, or PC61BM in the literature), C70, methyl phenyl-C71-butyrate (i.e., a fullerene derivative described as PCBM, [70]PCBM, or PC71BM in the literature), and fullerene derivatives described on the website of DAIKIN INDUSTRIES, LTD.

The average thickness of the photoelectric conversion layer is preferably from 50 to 400 nm, more preferably from 60 to 250 nm. When the average thickness is 50 nm or more, an undesired phenomenon can be effectively prevented in which the amount of light absorbed by the photoelectric conversion layer is so small that generation of carrier is insufficient. When the average thickness is 400 nm or less, the efficiency in transporting the carrier generated by light absorption can be effectively prevented from falling.

It has been found that the relationship between the thickness of the electron transport layer and that of the photoelectric conversion layer is a major factor in making flexible elements more excellent in resistance to bending.

Thus, an embodiment of the present invention defines the relationship between the average particle diameter D of the metal oxide particles and the average thickness T of the photoelectric conversion layer to satisfy 7.0 T/D 40.0.

When T/D is less than 7.0, when the organic thin-film solar cell is bent, defects due to leakage frequently occur. When the film thickness of the photoelectric conversion layer is 7 times or more of the average particle diameter of the metal oxide particles, leakage of the organic thin-film solar cell can be prevented. When T/D is in the range of from 7.0 to 40.0, upon bending of the element, the metal oxide particles are effectively prevented from breaking the photoelectric conversion layer to come into contact with the hole transport layer. When T/D is larger than 40.0, charge transportability of the photoelectric conversion layer is significantly reduced, so that the initial characteristics are degraded.

The average thickness T of the photoelectric conversion layer can be measured as follows. Procedure for Measuring Average Thickness T

After the photoelectric conversion layer is formed on the substrate by coating, 9 randomly-selected points of the layer is wiped off with a solvent, and the level difference at each point is measured with an instrument DEKTAK available from Bruker Corporation. The level differences thus measured are averaged to determine the average thickness T of the photoelectric conversion layer.

Alternatively, the thickness of the photoelectric conversion layer can also be measured from a cross-sectional image of the layer observed by TEM.

In the present disclosure, organic materials may be sequentially formed to form a planar junction interface. To increase the junction interface area, however, a bulk heterojunction is more preferably formed in which organic materials are three-dimensionally mixed.

The bulk heterojunction may be formed by applying a solution in which organic materials in molecular forms are mixed, followed by drying for removing the solvent. In a case in which the organic materials are highly-soluble materials, the solution is prepared by dissolving the organic materials in a solvent. Further, a heat treatment may be performed to optimize the aggregation state of each organic material.

Even when a poorly-soluble material is used, such a material can be dispersed in the solution in which other organic materials are dissolved, so that a mixed layer can be formed by application of the solution. In this case, a heat treatment may be further performed to optimize the aggregation state of each organic material.

A thin film of the organic material may be formed by, for example, spin coating, blade coating, slit die coating, screen printing, bar coating, mold coating, transfer printing, dipping-pulling, ink-jetting, spraying, and vacuum vapor deposition. The formation method is suitably selected from these methods according to the characteristics of the thin film of the organic material to be produced, for thickness control and for orientation control.

For example, when spin coating is performed, a solution containing the P-type semiconductor material represented by the general formula (1) described above and the N-type semiconductor material at a concentration of from 5 to 40 mg/mL is preferably used. Here, the concentration refers to the total mass of the P-type semiconductor material represented by the general formula (1) and the N-type semiconductor material relative to the volume of the solution containing the P-type semiconductor represented by the general formula (1), the N-type semiconductor material, and the solvent. By setting the concentration to be within the above-described range, it is easy to make the resulting photoelectric conversion layer homogeneous.

To remove the organic solvent, the resulting photoelectric conversion layer may be subjected to an annealing treatment under reduced pressures or under an inert atmosphere (e.g., nitrogen gas atmosphere, argon gas atmosphere). The annealing treatment is preferably performed at a temperature of from 40 to 300 degrees C., more preferably from 50 to 150 degrees C. There is a case in which the annealing process makes the stacked layers permeate each other at the interface to increase an effective area of contact, thereby increasing a short circuit current. The annealing process may be performed after formation of the electrode.

The solvent mixed with the P-type semiconductor material represented by the general formula (1) and the N-type semiconductor material is not particularly limited and can be appropriately selected according to the purpose. Examples thereof include, but are not limited to, methanol, ethanol, butanol, toluene, xylene, o-chlorophenol, acetone, ethyl acetate, ethylene glycol, tetrahydrofuran, dichloromethane, chloroform, dichloroethane, chlorobenzene, dichlorobenzene, trichlorobenzene, chloronaphthalene, dimethylformamide, dimethyl sulfoxide, N-methylpyrrolidone, and γ-butyrolactone. Each of these materials can be used alone or in combination with others. Among these, chlorobenzene, chloroform, and ortho-dichlorobenzene are preferable.

The solution may further contain other components as necessary.

The other components are not particularly limited and can be appropriately selected according to the purpose. Examples thereof include, but are not limited to, various additives such as diiodooctane, octanedithiol, and chloronaphthalene.

Hole Transport Layer

The hole transport layer is provided to improve hole collection efficiency.

Examples of compounds used for the hole transport layer include, but are not limited to, conductive polymers such as PEDOT:PSS (polyethylene dioxythiophene:polystyrene sulfonic acid), hole transporting organic compounds such as aromatic amine derivatives, and hole transporting inorganic compounds such as molybdenum oxide, tungsten oxide, vanadium oxide, and nickel oxide.

The hole transport layer containing these compounds may be formed by spin coating, sol-gel method, or sputtering.

In the present disclosure, molybdenum oxide is preferably used.

The average thickness of the hole transport layer is not particularly limited and can be appropriately selected according to the purpose, but is preferably from 1 to 50 nm, so that the layer thinly can cover the entire surface as much as possible.

Second Electrode

The second electrode is an electrode layer disposed on the hole transport layer.

Preferably, the second electrode is a metal electrode layer made of a metal having a relatively small work function.

Examples of the material used for the second electrode include, but are not limited to, gold, silver, aluminum, magnesium, and silver-magnesium alloys.

The film thickness of the second electrode is not particularly limited, but is preferably from 20 to 300 nm, more preferably from 50 to 200 nm, for photoelectric conversion performance.

The second electrode can be formed by any of various procedures such as wet film formation, dry film formation such as vapor deposition and sputtering, and printing.

Insulating Layer

The insulating layer is provided for preventing direct contact between the second electrode and the sealant. The insulating layer effectively prevents the sealant that is adhesive from peeling the electrode upon bending.

The insulating material used for the insulating layer is not particularly limited. Examples thereof include, but are not limited to, metal oxides such as SiOₓ, SiOₓN_{y}, and Al₂O₃, and polymers such as polyethylene, fluoropolymer, and polyparaxylylene. Among these, metal oxides are preferable.

The method for forming the insulating layer is not particularly limited. The insulating layer may be formed by, for example, vacuum deposition, sputtering, reactive sputtering, MBE (molecular beam epitaxy), plasma CVD (plasma-enhanced chemical vapor deposition), laser CVD, thermal CVD, gas source CVD, coating, printing, or transferring.

Sealant

The sealant is provided to block the entry of gas and moisture.

The sealant is not particularly limited in constituent member, but is generally constituted of an adhesive layer, a gas barrier layer, and a substrate, to have a film configuration which prevents permeation of moisture and oxygen.

The ability required for the sealant is generally expressed by water vapor transmittance. Although depending on the types of photoelectric conversion element and organic thin-film solar cell, the water vapor transmittance is preferably smaller than 1×10⁻² g/m²/day, and the lower the better.

Specific preferred examples of the sealant include a substrate having a gas barrier layer.

When the sealant is provided in the position opposite to the light receiving surface, light permeability is not necessary.

The adhesive layer of the sealant is not particularly limited as long as the above-described properties are secured. Materials generally used for sealing organic electroluminescent elements or organic transistors can be used therefor. Examples of such materials include, but are not limited to, thermosetting resin compositions, thermoplastic resin compositions, and photocurable resin compositions. More specific examples thereof include, but are not limited to, ethylene-vinyl acetate copolymer resin compositions, styrene-isobutylene resin compositions, hydrocarbon resin compositions, epoxy resin compositions, polyester resin compositions, acrylic resin compositions, urethane resin compositions, and silicone resin compositions. These polymer compositions can be given thermosetting property, thermoplasticity, or photocurability by chemical modification of the main chain, branched chain, or terminal, adjustment of molecular weight, and/or addition of additives.

Other Members

The photoelectric conversion element according to an embodiment of the present invention may include two or more photoelectric conversion layers stacked via one or more intermediate electrodes to form a tandem junction.

Use Application

In recent years, a photoelectric conversion element that efficiently generates power even with weak light has been required, particularly as an environmental power generation element. Light emitted from an LED light or a fluorescent lamp is an example of the weak light. Such weak light is generally called indoor light since it is mainly used indoor. The illuminance of such light is about 20 to 1,000 Lux, which is significantly weaker than that of direct sunlight (of about 100,000 Lux).

The photoelectric conversion element according to an embodiment of the present invention exhibits high conversion efficiency even with weak light such as the indoor light and can be applied to a power supply device by being combined with a circuit board that controls the generated current. Such a power supply device can be used for instruments such as electronic desk calculators and wristwatches. In addition, the power supply device using the photoelectric conversion element according to an embodiment of the present invention can be applied to cell phones, electronic organizers, and electronic papers.

Moreover, the power supply device using the photoelectric conversion element according to an embodiment of the present invention can also be used as an auxiliary power supply for lengthening the continuous operating time of rechargeable or dry-cell electronic apparatuses.

Furthermore, the power supply device can be applied to image sensors. On the other hand, development of wearable electronic apparatuses is in progress, and the power supply devices including the photoelectric conversion element are required to be flexible. The photoelectric conversion element according to an embodiment of the present invention can be sufficiently used as a power supply and an auxiliary power supply for electronic apparatuses required to have flexibility.

Organic Thin-Film Solar Cell

The photoelectric conversion element according to an embodiment of the present invention described above may be used as an organic thin-film solar cell.

The organic thin-film solar cell includes, on a substrate, a first electrode, an electron transport layer containing at least metal oxide particles, a photoelectric conversion layer containing at least two or more organic materials, a hole transport layer, a second electrode, and an insulating layer. The first electrode includes a transparent conductive thin-film layer (a), a metal thin-film layer, and a transparent conductive thin-film layer (b). The average particle diameter D of the metal oxide particles and the average thickness T of the photoelectric conversion layer satisfy the relation 7.0≤T/D≤40.0.

The substrate, the first electrode, the electron transport layer, the photoelectric conversion layer, the hole transport layer, the second electrode, the insulating layer, and the sealant are the same as those described above for the photoelectric conversion element.

Preferred examples of the organic thin-film solar cell according to an embodiment of the present invention includes an inverted organic thin-film solar cell in which the surface on the side of the substrate 2 constitutes a light receiving surface.

Photoelectric Conversion Element Module

A photoelectric conversion element module according to an embodiment of the present invention is provided with a plurality of the photoelectric conversion elements according to an embodiment of the present invention. The photoelectric conversion elements are disposed at respective positions where each of which can easily receive light, and may be connected either in tandem or in parallel.

Electronic Apparatus

An electronic apparatus according to an embodiment of the present invention contains the photoelectric conversion element and/or photoelectric conversion element module according to an embodiment of the present invention, and a device configured to operate by power generated as the photoelectric conversion element and/or photoelectric conversion element module undergoes photoelectric conversion.

Power Supply Module

A power supply module according to an embodiment of the present invention includes the photoelectric conversion element and/or photoelectric conversion element module according to an embodiment of the present invention and a power supply IC (integrated circuit), and further includes other devices as necessary.

Specific examples of the electronic apparatus, containing the photoelectric conversion element and/or photoelectric conversion element module and a device configured to operate by power generated the element and/or module, are described below.

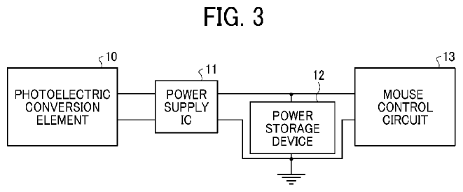

FIG. 3 is a block diagram of a mouse for a personal computer as the electronic apparatus according to an embodiment of the present invention.

As illustrated in FIG. 3, a photoelectric conversion element 10, a power supply IC 11, and a power storage device 12 are combined and connected to a power supply of a mouse control circuit 13 to supply power. When the mouse is not in use, the power storage device 12 gets charged. The mouse is operated by the stored power without requiring any wiring or battery replacement. Since no battery is required, weight reduction is also possible.

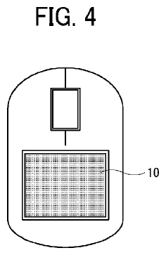

FIG. 4 is a schematic external view of the mouse illustrated in FIG. 3.

Referring to FIG. 4, the photoelectric conversion element 10, the power supply IC 11, and the power storage device 12 are mounted inside the mouse. However, the upper part of the photoelectric conversion element 10 is covered with a transparent casing so that the photoelectric conversion element 10 can be exposed to light. It is also possible to form the entire casing of the mouse with a transparent resin. The arrangement of the photoelectric conversion element 10 is not limited to that. For example, the photoelectric conversion element 10 may be arranged at a position where the photoelectric conversion element 10 can be irradiated with light even when the mouse is covered with a hand.

Next, another embodiment of the electronic apparatus, containing the photoelectric conversion element and/or photoelectric conversion element module and a device configured to operate by power generated by the element and/or module, is described below.

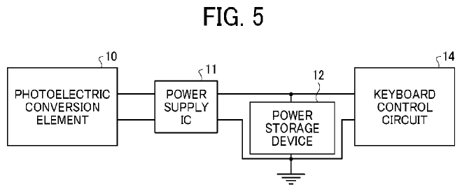

FIG. 5 is a block diagram of a keyboard for a personal computer as the electronic apparatus according to an embodiment of the present invention.

As illustrated in FIG. 5, a photoelectric conversion element 10, a power supply IC 11, and a power storage device 12 are combined and connected to a power supply of a keyboard control circuit 14 to supply power. When the keyboard is not in use, the power storage device 12 gets charged. The keyboard is operated by the stored power without requiring any wiring or battery replacement. Since no battery is required, weight reduction is also possible.

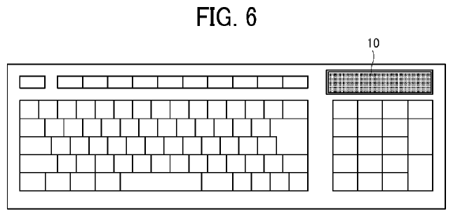

FIG. 6 is a schematic external view of the keyboard illustrated in FIG. 5.

Referring to FIG. 6, the photoelectric conversion element 10, the power supply IC 11, and the power storage device 12 are mounted inside the keyboard. However, the upper part of the photoelectric conversion element 10 is covered with a transparent casing so that the photoelectric conversion element 10 can be exposed to light. It is also possible to form the entire casing of the keyboard with a transparent resin. The arrangement of the photoelectric conversion element 10 is not limited to that.

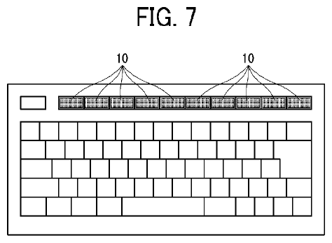

In the case of a small keyboard having a small space for installing the photoelectric conversion element 10, the photoelectric conversion element 10 with a small size may be embedded in a part of the key as illustrated in FIG. 7.

Next, another embodiment of the electronic apparatus, containing the photoelectric conversion element and/or photoelectric conversion element module and a device configured to operate by power generated by the element and/or module, is described below.

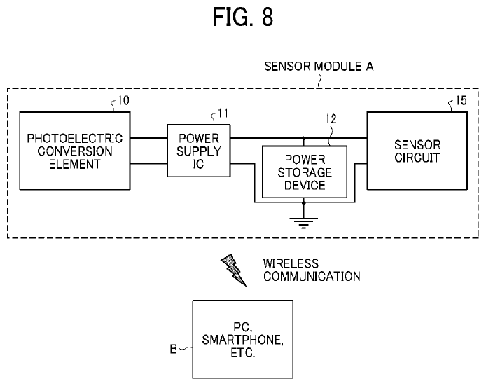

FIG. 8 is a block diagram of a sensor as the electronic apparatus according to an embodiment of the present invention.

As illustrated in FIG. 8, a photoelectric conversion element 10, a power supply IC 11, and a power storage device 12 are combined and connected to a power supply of a sensor circuit 15 to supply power. Thus, a sensor module A is configured which needs neither connection to an external power supply nor battery replacement. The sensor module A may be applied to various sensors for sensing, for example, temperature and humidity, illuminance, human motion, CO₂, acceleration, UV, noise, geomagnetism, or barometric pressure. The sensor module A is configured to periodically sense a measuring target and transmit the read data to a PC (personal computer), a smartphone, etc., denoted as B in FIG. 8, by wireless communication.

With the advent of the Internet of Things (IoT) society, sensors are expected to surge. It takes a lot of time and effort to replace batteries of innumerable sensors one by one, which is not realistic. In addition, sensors may be located in places where battery replacement is difficult, such as on ceilings and walls, which also impairs operability. It is a great advantage that power is supplied by the photoelectric conversion element. It is also a great advantage that the photoelectric conversion element according to an embodiment of the present invention provides high output even under low illuminance with a small dependency on light incident angle and thus provides a high degree of freedom in installation.

Next, another embodiment of the electronic apparatus, containing the photoelectric conversion element and/or photoelectric conversion element module and a device configured to operate by power generated by the element and/or module, is described below.

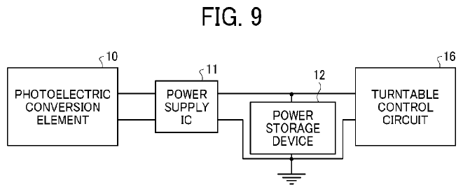

FIG. 9 is a block diagram of a turntable as the electronic apparatus according to an embodiment of the present invention.

As illustrated in FIG. 9, a photoelectric conversion element 10, a power supply IC 11, and a power storage device 12 are combined and connected to a power supply of a turntable control circuit 16 to supply power. Thus, a turntable is configured which needs neither connection to an external power supply nor battery replacement.

The turntable can be used for displaying goods in a showcase, where it looks bad if wiring of the power supply is exposed. The displayed goods have to be removed at the time of battery replacement, which takes a lot of time and effort. The use of the photoelectric conversion element according to an embodiment of the present invention can solve such problems.

Use Application

The electronic apparatus containing the photoelectric conversion element and/or photoelectric conversion element module according to an embodiment of the present invention and a device configured to operate by power generated by the element/module is described above for the purpose of illustration. The applications of the photoelectric conversion element and photoelectric conversion element module are not limited thereto.

The photoelectric conversion element or photoelectric conversion element module may be combined with a circuit board that controls the generated current to be applied as a power supply device.

Such a power supply device can be used for instruments such as electronic desk calculators, wristwatches, cell phones, electronic organizers, and electronic papers. Moreover, the power supply device using the photoelectric conversion element can also be used as an auxiliary power supply for lengthening the continuous operating time of rechargeable or dry-cell electronic apparatuses.

The photoelectric conversion element and photoelectric conversion element module according to some embodiments of the present invention can function as a stand-alone power supply and can operate a device using power generated upon photoelectric conversion. Since the photoelectric conversion element and photoelectric conversion element module according to some embodiments of the present invention can generate power upon irradiation with light, it is not necessary to connect the electronic apparatus to a power supply or to replace batteries. Therefore, it is possible to operate or carry around the electronic apparatus even in a place where there is no power supply facility, or to operate the electronic apparatus without replacing batteries in a place where battery replacement is difficult. In the case of using a dry cell, the electronic apparatus may become heaver or larger in size, which may hinder installation of the electronic apparatus on a wall or ceiling or carrying of the electronic apparatus. On the other hand, the photoelectric conversion element and photoelectric conversion element module according to some embodiments of the present invention are lightweight and thin, providing a high degree of freedom in installation and a great advantage in wearing and carrying.

As described above, the photoelectric conversion element and photoelectric conversion element module according to some embodiments of the present invention can be used as a stand-alone power supply and can be combined with various electronic apparatuses such as: electronic desktop calculators, wristwatches, cell phones, electronic organizers, display devices such as electronic papers, accessories for PCs such as mice and keyboards, various sensor devices such as temperature and humidity sensors and motion detecting sensors, transmitters such as beacons and GPS (global position system), auxiliary lights, and remote controllers.

The photoelectric conversion element and photoelectric conversion element module according to some embodiments of the present invention can generate power even with low illuminance light, so they can generate power indoors and even in a shade, providing a wide range of application. In addition, high degree of safety is provided sine there is no liquid leakage as in dry batteries and there is no risk of accidental ingestion as in button batteries. Moreover, the photoelectric conversion element and photoelectric conversion element module can also be used as an auxiliary power supply for lengthening the continuous operating time of rechargeable or dry-cell electronic apparatuses. By combining the photoelectric conversion element and/or photoelectric conversion element module according to an embodiment of the present invention with a device configured to operate by power generated upon photoelectric conversion of the element and/or module, an electronic apparatus is provided which is lightweight, easy to use, highly free in installation, free of replacement, superior in safety, and also effective in reducing environmental impact.

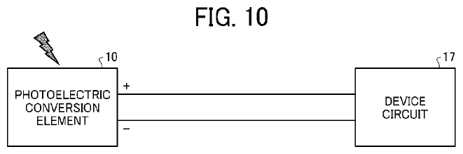

FIG. 10 is a block diagram of the electronic apparatus according to an embodiment of the present invention in which the photoelectric conversion element according to an embodiment of the present invention is combined with a device configured to operate by power generated upon photoelectric conversion of the element. The photoelectric conversion element 10 generates power upon irradiation with light, and the power can be extracted. The circuit of the device (“device circuit 17”) can be operated by the power.

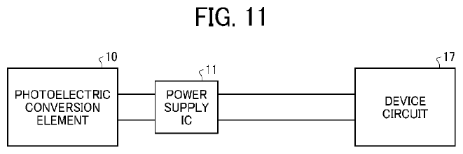

However, since the output of the photoelectric conversion element 10 fluctuates depending on the ambient illuminance, the electronic apparatus illustrated in FIG. 10 may not be able to operate stably. In this case, as illustrated in FIG. 11, a power supply IC 11 for the photoelectric conversion element 10 can be mounted between the photoelectric conversion element 10 and the device circuit 17 for reliable supply of voltage to the circuit.

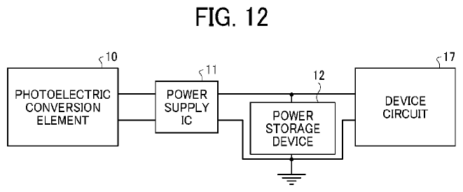

Although the photoelectric conversion element can generate power upon irradiation with light of sufficient illuminance, if the illuminance is insufficient, desired power cannot be generated. This may be a drawback of the photoelectric conversion element. In this case, as illustrated in FIG. 12, a power storage device 12 such as a capacitor can be mounted between the power supply IC 11 and the device circuit 17 to make it possible to charge the power storage device 12 with surplus power from the photoelectric conversion element 10. Thus, the power stored in the power storage device 12 can be supplied to the device circuit 17 for reliable operation of the device, even when the illuminance is too low or no light reaches the photoelectric conversion element 10.

When the electronic apparatus combining the photoelectric conversion element and/or photoelectric conversion element module according to an embodiment of the present invention with the device circuit is further combined with the power supply IC and/or the power storage device, the electronic apparatus becomes possible to operate even in an environment without power supply and to reliably drive without battery replacement, making the most of the merits of the photoelectric conversion element.

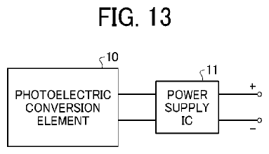

On the other hand, the photoelectric conversion element and/or photoelectric conversion element module according to an embodiment of the present invention can also be used for a power supply module. For example, as illustrated in FIG. 13, by connecting the photoelectric conversion element 10 according to an embodiment of the present invention to a power supply IC 11 for the photoelectric conversion element 10, a direct-current power supply module is configured which supplies the power generated by photoelectric conversion of the photoelectric conversion element 10 at a constant voltage level from the power supply IC 11.

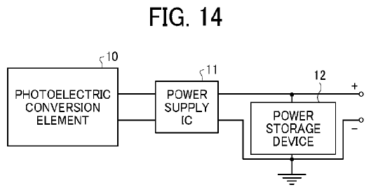

Furthermore, as illustrated in FIG. 14, by mounting a power storage device 12 to the power supply IC 11, it becomes possible to charge the power storage device 12 with the power generated by the photoelectric conversion element 10. Thus, a power supply module is configured which is capable of supplying power even when the illuminance is too low or no light reaches the photoelectric conversion element 10.

The power supply modules illustrated in FIGS. 13 and 14 can be used as power supply modules without battery replacement as in conventional primary batteries.

### EXAMPLES

Further understanding can be obtained by reference to certain specific examples which are provided herein for the purpose of illustration only and are not intended to be limiting.

### Example 1

Transparent Electrode

A polyethylene terephthalate (PET) substrate with a gas barrier film, on which a film of IAI (ITO/Ag/ITO with respective thicknesses of 40 nm/7 nm/40 nm)) was formed, was procured from GEOMATEC Co., Ltd.

Preparation of Solar Cell

1. Formation of Electron Transport Layer

The IAI-film-formed PET film with a gas barrier film (15Ω/□) was spin-coated with zinc oxide nanoparticles (available from Sigma-Aldrich, having an average particle diameter of 12 nm) at 3,000 rpm and dried at 80 degrees C. for 10 minutes. Thus, an electron transport layer having a film thickness of 30 nm was formed.

2. Formation of Photoelectric Conversion Layer

Preparation of Photoelectric Conversion Layer Coating Liquid A

First, 10 mg of P3HT (available from Sigma-Aldrich, Mn (number average molecular weight)=54,000) and 10 mg of PC61BM (available from Sigma-Aldrich) were dissolved in 1 mL of chlorobenzene.

The electron transport layer was spin-coated with the photoelectric conversion layer coating liquid A at 1,000 rpm, thus forming a photoelectric conversion layer having a thickness of about 150 nm.

3. Formation of Hole Transport Layer and Upper Electrode

On the photoelectric conversion layer, a hole transport layer comprising molybdenum oxide (available from Kojundo Chemical Laboratory Co., Ltd.) having a thickness of 10 nm and an electrode layer comprising silver having a thickness of 100 nm were sequentially formed by vacuum vapor deposition.

Thus, a solar cell element (photoelectric conversion element) was prepared.

4. Formation of Insulating Layer

The above-prepared solar cell element was spin-coated with an aluminum oxide nanoparticle dispersion liquid (available from Sigma-Aldrich) at 1,500 rpm, thus forming an insulating layer having a thickness of 300 nm.

5. Sealing

A sealing substrate composed of an adhesive layer formed on an aluminum-coated PET film was applied onto the insulating layer of the solar cell element using a roll laminator so as to cover the solar cell element. The PET substrate of the solar cell element and the sealing substrate were attached and sealed under a normal-temperature nitrogen atmosphere.

Thus, a solar cell was prepared.

Measurement of HOMO Level

The HOMO level was measured in the photoelectric conversion layer using an instrument AC-2 available from Riken Keiki Co., Ltd.

As a result, the HOMO level was 4.9 eV.

Evaluation of Solar Cell Characteristics

An output characteristics (Pmax) under white LED irradiation (0.07 mW/cm²) of the above-prepared solar cell was measured.

The used white LED was a desk lamp CDS-90a available from Cosmotechno Co., Ltd. The used tester was a solar cell evaluating system As-510-PV03 available from NF Corporation. The output of the LED light source was measured by a spectral color luminometer SPECTROMASTER C-7000 available from SEKONIC CORPORATION. The results are presented in the column of “Initial Stage” in Table 1.

Bend Test and Evaluation of Solar Cell Characteristics after the Test

A bend test according to the Japanese Industrial Standards (JIS) K5600-5-1 was repeated 100 times using a mandrel having a diameter of 32 mm. Subsequently, solar cell characteristics after the bend test was evaluated (output characteristics was measured) in the same manner as the above-described procedure in “Evaluation of Solar Cell Characteristics”. The results are presented in the column of “After Bend Test” in Table 1.

### Example 2

The procedure in Example 1 was repeated except for replacing the photoelectric conversion layer coating liquid A with a photoelectric conversion layer coating liquid B prepared as below and changing the film thickness of the photoelectric conversion layer to 90 nm. The results are presented in Table 1.

The HOMO level was 5.1 eV.

Preparation of Photoelectric Conversion Layer Coating Liquid B

The photoelectric conversion layer coating liquid B was prepared by dissolving 10 mg of PTB-7 (available from Ossila Ltd, Mn=78,000) and 15 mg of PC61BM (available from Sigma-Aldrich) in 1 mL of chlorobenzene containing 3% by volume of 1,8-diiodooctane.

### Example 3

The procedure in Example 1 is repeated except for replacing the photoelectric conversion layer coating liquid A with a photoelectric conversion layer coating liquid C as prepared below and changing the process for preparing the solar cell as described below. The results are presented in Table 1.

The HOMO level was 5.2 eV.

Preparation of Photoelectric Conversion Layer Coating Liquid C

The photoelectric conversion layer coating liquid C was prepared by dissolving 15 mg of an Example Compound 1 (Mn=1,554) and 10 mg of an Example Compound 2 in 1 mL of chloroform.

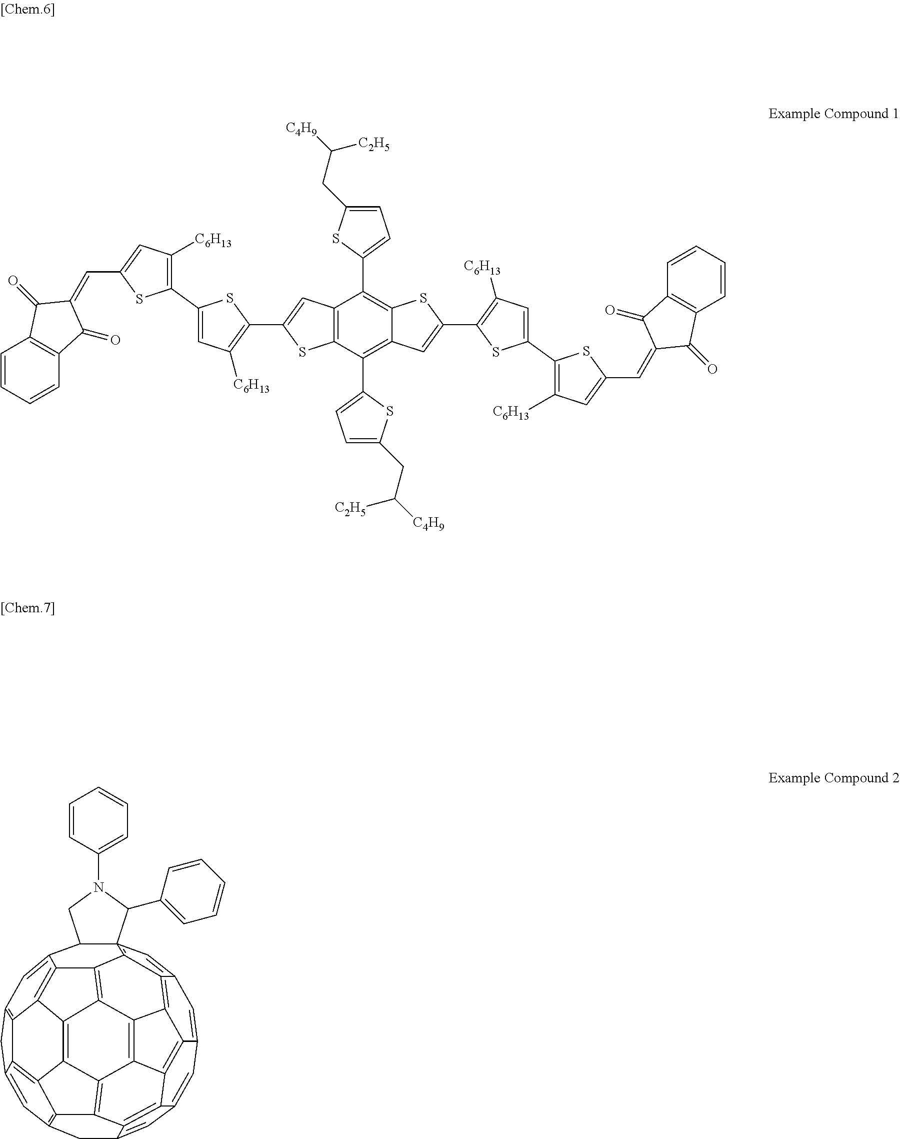

Preparation of Solar Cell

1. Formation of Electron Transport Layer

The IAI-film-formed PET film with a gas barrier film (15Ω/□) was spin-coated with zinc oxide nanoparticles (available from Sigma-Aldrich, having an average particle diameter of 12 nm) at 1,000 rpm and dried at 80 degrees C. for 10 minutes. Thus, an electron transport layer having a film thickness of 40 nm was formed.

2. Formation of Photoelectric Conversion Layer

The electron transport layer was spin-coated with the photoelectric conversion layer coating liquid C at 600 rpm, thus forming a photoelectric conversion layer having a thickness of about 150 nm.

3. Formation of Hole Transport Layer and Upper Electrode

On the photoelectric conversion layer, a hole transport layer comprising molybdenum oxide (available from Kojundo Chemical Laboratory Co., Ltd.) having a thickness of 10 nm and an electrode layer comprising silver having a thickness of 100 nm were sequentially formed by vacuum vapor deposition.

Thus, a solar cell element was prepared.

4. Formation of Insulating Layer

The above-prepared solar cell element was spin-coated with an aluminum oxide nanoparticle dispersion liquid (available from Sigma-Aldrich) at 1,500 rpm, thus forming an insulating layer having a thickness of 300 nm.

5. Sealing

A sealing substrate composed of an adhesive layer formed on an aluminum-coated PET film was applied onto the insulating layer of the solar cell element using a roll laminator so as to cover the solar cell element. The PET substrate of the solar cell element and the sealing substrate were attached and sealed under a normal-temperature nitrogen atmosphere.

Thus, a solar cell was prepared.

### Example 4

The procedure in Example 3 was repeated except for changing the process for preparing the solar cell as described below. The results are presented in Table 1.

Preparation of Solar Cell

1. Formation of Electron Transport Layer

The IAI-film-formed PET film with a gas barrier film (15Ω/□) was spin-coated with zinc oxide nanoparticles (available from Sigma-Aldrich, having an average particle diameter of 12 nm) at 1,000 rpm and dried at 80 degrees C. for 10 minutes. Thus, an electron transport layer having a film thickness of 40 nm was formed.

Further, an ethanol solution of dimethylaminobenzoic acid having a concentration of 1 mg/mL was prepared and formed into a film on the zinc oxide nanoparticles at 1,500 rpm.

2. Formation of Photoelectric Conversion Layer

Subsequently, the electron transport layer was spin-coated with the photoelectric conversion layer coating liquid C at 600 rpm, thus forming a photoelectric conversion layer of about 150 nm.

3. Formation of Hole Transport Layer and Upper Electrode

On the photoelectric conversion layer, a hole transport layer comprising molybdenum oxide (available from Kojundo Chemical Laboratory Co., Ltd.) having a thickness of 10 nm and an electrode layer comprising silver having a thickness of 100 nm were sequentially formed by vacuum vapor deposition.

Thus, a solar cell element was prepared.

4. Formation of Insulating Layer

The above-prepared solar cell element was spin-coated with an aluminum oxide nanoparticle dispersion liquid (available from Sigma-Aldrich) at 1,500 rpm, thus forming an insulating layer having a thickness of 300 nm.

5. Sealing

A sealing substrate composed of an adhesive layer formed on an aluminum-coated PET film was applied onto the insulating layer of the solar cell element using a roll laminator so as to cover the solar cell element. The PET substrate of the solar cell element and the sealing substrate were attached and sealed under a normal-temperature nitrogen atmosphere.

Thus, a solar cell was prepared.

### Example 5

The procedure in Example 4 was repeated except for replacing the photoelectric conversion layer coating liquid C with a photoelectric conversion layer coating liquid D as prepared below. The results are presented in Table 1.

Preparation of Photoelectric Conversion Layer Coating Liquid D

The photoelectric conversion layer coating liquid D was prepared by dissolving 15 mg of the Example Compound 1 and 10 mg of PC61BM (E100H available from Frontier Carbon Corporation) in 1 mL of chloroform.

### Example 6

The procedure in Example 4 was repeated except for replacing the photoelectric conversion layer coating liquid C with a photoelectric conversion layer coating liquid E as prepared below. The results are presented in Table 1.

The HOMO level was 5.3 eV.

Preparation of Photoelectric Conversion Layer Coating Liquid E

The photoelectric conversion layer coating liquid E was prepared by dissolving 15 mg of an Example Compound 3 (Mn=1,463) and 10 mg of the Example Compound 2 in 1 mL of chloroform.

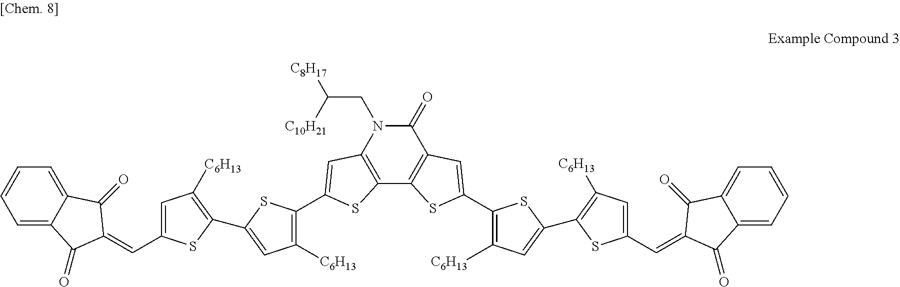

### Example 7

The procedure in Example 4 was repeated except for changing the film thickness of the photoelectric conversion layer to 90 nm. The results are presented in Table 1.

### Example 8

The procedure in Example 4 was repeated except for forming the electron transport layer with zinc oxide nanoparticles having an average particle diameter of 30 nm (available from Tayca Corporation) and changing the film thickness of the photoelectric conversion layer to 220 nm. The results are presented in Table 1.

### Example 9

The procedure in Example 4 was repeated except for changing the film thickness of the photoelectric conversion layer to 300 nm. The results are presented in Table 1.

### Example 10

The procedure in Example 4 was repeated except for replacing the photoelectric conversion layer coating liquid C with a photoelectric conversion layer coating liquid F as prepared below. The results are presented in Table 1.

The HOMO level was 5.3 eV.

Preparation of Photoelectric Conversion Layer Coating Liquid F

The photoelectric conversion layer coating liquid F was prepared by dissolving 12.5 mg of an Example Compound 4 (Mn=2,029) and 12.5 mg of the Example Compound 2 in 1 mL of chloroform.

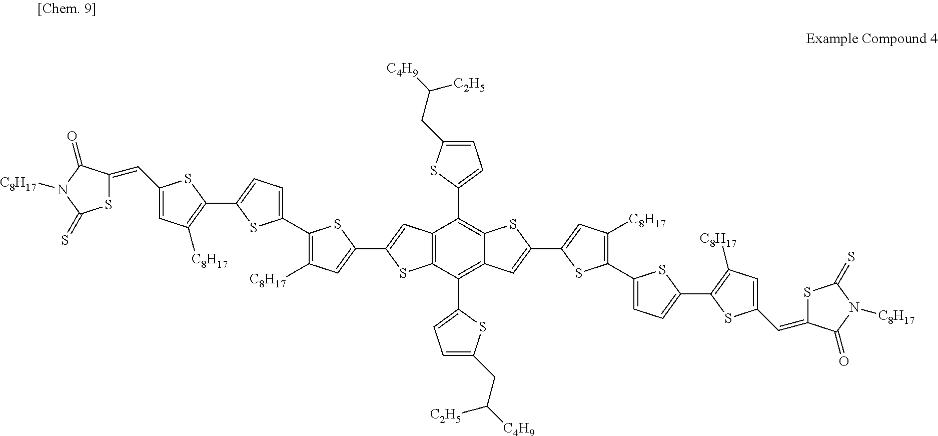

### Example 11

The procedure in Example 4 was repeated except for replacing the photoelectric conversion layer coating liquid C with a photoelectric conversion layer coating liquid G as prepared below and changing the film thickness of the photoelectric conversion layer to 100 nm. The results are presented in Table 1.

The HOMO level was 5.4 eV.

Preparation of Photoelectric Conversion Layer Coating Liquid G

The photoelectric conversion layer coating liquid G was prepared by dissolving 12.5 mg of PCDTBT (available from Ossila Ltd, Mn=16,200) and 12.5 mg of the Example Compound 2 in 1 mL of chloroform.

### Example 12

The procedure in Example 4 was repeated except for changing the process for preparing the electron transport layer as described below and changing the film thickness of the photoelectric conversion layer to 100 nm. The results are presented in Table 1.

Preparation of Electron Transport Layer

The IAI-film-formed PET film with a gas barrier film (15Ω/□) was spin-coated with aluminum-doped zinc oxide nanoparticles (available from Sigma-Aldrich, having an average particle diameter of 12 nm) at 1,000 rpm and dried at 80 degrees C. for 10 minutes. Thus, an electron transport layer having a film thickness of 40 nm was formed.

### Example 13

The procedure in Example 4 was repeated except for changing the process for preparing the electron transport layer as described below and changing the film thickness of the photoelectric conversion layer to 60 nm. The results are presented in Table 1.

Preparation of Electron Transport Layer

The IAI-film-formed PET film with a gas barrier film (15Ω/□) was spin-coated with tin oxide nanoparticles (available from Sigma-Aldrich, having an average particle diameter of 7 nm) at 1,000 rpm and dried at 80 degrees C. for 10 minutes. Thus, an electron transport layer having a film thickness of 20 nm was formed.

### Example 14

The procedure in Example 4 was repeated except for changing the process for preparing the hole transport layer as described below. The results are presented in Table 1.

Preparation of Hole Transport Layer

A hole transport layer having a thickness of 10 nm was formed on the photoelectric conversion layer by vapor deposition of tungsten oxide (available from Kojundo Chemical Laboratory Co., Ltd.).

### Example 15

The procedure in Example 4 was repeated except for changing the process for preparing the hole transport layer as described below. The results are presented in Table 1.

Preparation of Hole Transport Layer

A hole transport layer having a thickness of 10 nm was formed on the photoelectric conversion layer by vapor deposition of vanadium oxide (available from Kojundo Chemical Laboratory Co., Ltd.).

### Example 16

The procedure in Example 4 was repeated except for changing the process for preparing the hole transport layer as described below. The results are presented in Table 1.

Preparation of Hole Transport Layer

A hole transport layer having a thickness of 30 nm was formed with P-30 (available from Avantama AG, molybdenum oxide nanoparticle dispersion liquid containing PEDTT:PSS) on the photoelectric conversion layer by spin coating.

### Example 17

The procedure in Example 4 was repeated except for changing the film thickness of the photoelectric conversion layer to 360 nm. The results are presented in Table 1.

### Example 18

The procedure in Example 4 was repeated except for changing the film thickness of the photoelectric conversion layer to 480 nm. The results are presented in Table 1.

### Comparative Example 1

The procedure in Example 4 was repeated except for changing the transparent electrode with ITO (having a thickness of 100 nm, available from GEOMATEC Co., Ltd.). The results are presented in Table 1.

### Comparative Example 2

The procedure in Example 4 was repeated except for forming the electron transport layer with zinc oxide nanoparticles having an average particle diameter of 30 nm (available from Tayca Corporation). The results are presented in Table 1.

### Comparative Example 3

The procedure in Example 4 was repeated except for eliminating the process for forming the insulating layer. The results are presented in Table 1.

### Comparative Example 4

The procedure in Example 4 was repeated except for changing the film thickness of the photoelectric conversion layer to 80 nm. The results are presented in Table 1.

### Comparative Example 5

The procedure in Example 4 was repeated except for changing the film thickness of the photoelectric conversion layer to 600 nm. The results are presented in Table 1.

| | Initial Stage | After Bend Test | T/D |
|---|---|---|---|
| Example 1 | 7.6% | 7.4% | 12.5 |
| Example 2 | 9.3% | 9.3% | 7.5 |
| Example 3 | 12.5% | 12.6% | 12.5 |
| Example 4 | 16.8% | 16.7% | 12.5 |
| Example 5 | 14.4% | 14.2% | 12.5 |
| Example 6 | 18.3% | 18.4% | 12.5 |
| Example 7 | 12.5% | 12.4% | 7.5 |
| Example 8 | 13.2% | 13.5% | 7.3 |
| Example 9 | 10.5% | 10.7% | 25.0 |
| Example 10 | 12.4% | 11.3% | 12.5 |
| Example 11 | 10.1% | 10.0% | 8.3 |
| Example 12 | 13.5% | 13.3% | 8.3 |
| Example 13 | 12.7% | 11.9% | 8.6 |
| Example 14 | 12.7% | 11.9% | 12.5 |
| Example 15 | 14.3% | 13.9% | 12.5 |
| Example 16 | 13.2% | 13.1% | 12.5 |
| Example 17 | 9.5% | 9.7% | 30.0 |
| Example l8 | 8.9% | 9.0% | 40.0 |
| Comparative Example 1 | 13.5% | 13.7% | 12.5 |
| Comparative Example 2 | 13.9% | 5.5% | 5.0 |
| Comparative Example 3 | 13.8% | 1.3% | 12.5 |
| Comparative Example 4 | 10.1% | 0.9% | 6.7 |
| Comparative Example 5 | 3.1% | 2.9% | 50.0 |

As indicated by the above Examples, the organic thin-film solar cells containing the photoelectric conversion element according to an embodiment of the present invention exhibited high output characteristics, which did not decrease even after the bend test, as well as high photoelectric conversion efficiency. By contrast, the organic thin-film solar cells of the Comparative Examples exhibited d lower output characteristics as compared to the Examples. Furthermore, in many of the Comparative Examples, the output characteristics and conversion efficiency were significantly reduced after the bend test.

Accordingly, a photoelectric conversion element having excellent photoelectric conversion performance and excellent resistance to bending, capable of maintaining high photoelectric conversion performance even when subjected to a bending processing, is provided.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

This patent application is based on and claims priority pursuant to 35 U.S.C. § 119(a) to Japanese Patent Application Nos. 2018-143869 and 2019-016996, filed on Jul. 31, 2018 and Feb. 1, 2019, respectively, in the Japan Patent Office, the entire disclosure of each of which is hereby incorporated by reference herein.

### REFERENCE SIGNS LIST

1 Organic thin-film solar cell
2 Substrate
3 First electrode
4 Electron transport layer
5 Photoelectric conversion layer
6 Hole transport layer
7 Second electrode
8 Insulating layer
9 Sealant
31 Transparent conductive thin-film layer (a)
32 Metal thin-film layer
33 Transparent conductive thin-film layer (b)
10 Photoelectric conversion element
11 Power supply IC
12 Power storage device
13 Mouse control circuit
14 Keyboard control circuit
15 Sensor circuit
16 Turntable control circuit
17 Device circuit
A Sensor module
B PC, smartphone, etc.

1. A photoelectric conversion element comprising:
a substrate;
a first electrode overlying the substrate, comprising:
a transparent conductive thin-film layer (a);
a metal thin-film layer; and
a transparent conductive thin-film layer (b);
an electron transport layer overlying the substrate, containing metal oxide particles;
a photoelectric conversion layer overlying the substrate, containing two or more organic materials;
a hole transport layer overlying the substrate;
a second electrode overlying the substrate; and
an insulating layer overlying the substrate,
wherein the following relation is satisfied:
7.0≤T/D≤40.0
where D represents an average particle diameter of the metal oxide particles and T represents an average thickness of the photoelectric conversion layer.

2. The photoelectric conversion element according to claim 1, wherein the metal oxide particles comprise at least one of zinc oxide, titanium oxide, and tin oxide.

3. The photoelectric conversion element according to claim 1, wherein the hole transport layer contains at least one metal oxide selected from molybdenum oxide, tungsten oxide, and vanadium oxide.

4. The photoelectric conversion element according to claim 1, wherein one of the two or more organic materials comprises a donor organic material.

5. The photoelectric conversion element according to claim 4, wherein the donor organic material comprises a π electron conjugated compound having a highest occupied molecular orbital (HOMO) level of from 5.1 to 5.5 eV.

6. The photoelectric conversion element according to claim 4, wherein the donor organic material comprises a P-type semiconductor comprising a low-molecular conjugated compound having a number average molecular weight of 10,000 or less.

7. The photoelectric conversion element according to claim 1, wherein one of the two or more organic materials comprises a compound represented by the following general formula (1): 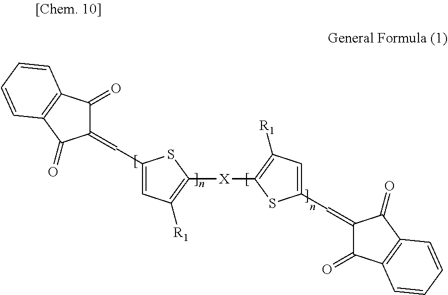
where R₁ represents an alkyl group having 2 to 8 carbon atoms, n represents an integer of 1 or 2, and X represents the following general formula (2) or (3): 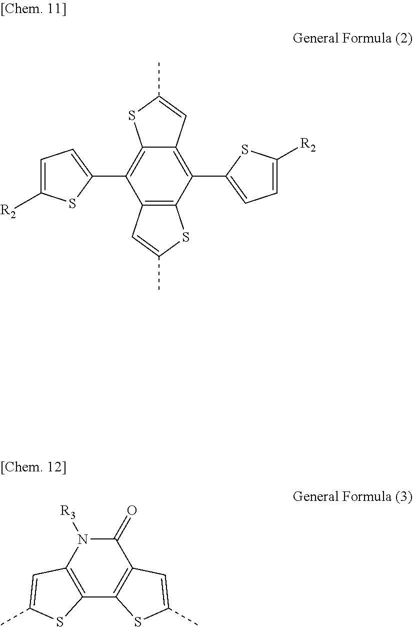
where each of R₂ and R₃ independently represents a straight-chain or branched alkyl group.

8. The photoelectric conversion element according to claim 4, wherein other one of the two or more organic materials comprises a fullerene derivative.

9. The photoelectric conversion element according to claim 1, wherein the electron transport layer comprises:
a first electron transport layer containing the metal oxide particles; and
a second electron transport layer disposed between the first electron transport layer and the photoelectric conversion layer, the second electron transport layer containing an amine compound represented by the following general formula (4): 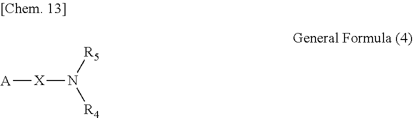
where each of R₄ and R₅ independently represents a substituted or unsubstituted alkyl group having 1 to 4 carbon atoms, or R₄ and R₅ share bond connectivity to form a ring; X represents a divalent aromatic group having 6 to 14 carbon atoms or an alkyl group having 1 to 4 carbon atoms; and A represents any of the following substituents.
—COOH
—P(═O)(OH)₂
—Si(OH)₃ [Chem. 14]

10. The photoelectric conversion element according to claim 1, wherein the photoelectric conversion element is used as an organic thin-film solar cell.

11. A photoelectric conversion element module comprising a plurality of photoelectric conversion elements, each photoelectric conversion element being the photoelectric conversion element according to claim 1.

12. An organic thin-film solar cell comprising:
a substrate;
a first electrode overlying the substrate, comprising:
a transparent conductive thin-film layer (a);
a metal thin-film layer; and
a transparent conductive thin-film layer (b);
an electron transport layer overlying the substrate, containing metal oxide particles;
a photoelectric conversion layer overlying the substrate, containing two or more organic materials;
a hole transport layer overlying the substrate;
a second electrode overlying the substrate; and
an insulating layer overlying the substrate,
wherein the following relation is satisfied:
7.0≤T/D≤40.0
where D represents an average particle diameter of the metal oxide particles and T represents an average thickness of the photoelectric conversion layer.

13. An electronic apparatus, comprising:
the photoelectric conversion element module according to claim 11; and
a device configured to operate by power generated as the at least one of the photoelectric conversion elements and the photoelectric conversion element module undergoes photoelectric conversion.

14. A power supply module, comprising:
the photoelectric conversion element module according to claim 11; and
a power supply integrated circuit.
